(19) United States
(12) Patent Application Publication
(10) Pub. No.: US 2026/0215051 A1
(43) Pub. Date: Jul. 23, 2026

(54) LIGHT-TRANSMITTING DEVICE MODULE

(71) Applicant: AUTONICS CORPORATION, Busan (KR)

(72) Inventor: Dong Geun OH, Incheon (KR)

(73) Assignee: AUTONICS CORPORATION, Busan (KR)

(21) Appl. No.: 19/139,190

(22) PCT Filed: Dec. 14, 2023
(86) PCT No.: PCT/KR2023/020694

§ 371 Date: Jun. 13, 2025

(30) Foreign Application Priority Data
Dec. 16, 2022 (KR) 10-2022-0177089

(51) Int. Cl. H10H 29/20; G02B 6/42; H10F 55/25; H10H 20/856; H10H 29/85

(52) U.S. Cl. CPC H10H 29/20; G02B 6/4214; G02B 6/4257; H10F 55/25; H10H 20/856; H10H 29/8506

(57) ABSTRACT

A light-transmitting device module according to an embodiment of the present invention comprises: a metal frame; a light-transmitting device chip mounted on the upper surface of the metal frame; a light-receiving device chip mounted on the metal frame to monitor the intensity of light emitted from the light-emitting device chip, and located at a point apart from the light-emitting device chip; a housing coupled to the upper surface of the metal frame to spatially partition the light-emitting device chip from the light-receiving device chip; and a reflector placed on the upper surface of the housing, wherein the housing includes a light-transmitting portion that is opened to receive the light-transmitting device chip, a light-receiving portion that is opened to receive the light-receiving device chip, and a partition wall that partitions the light-transmitting portion from the light-receiving portion, and a light passage groove is formed in the partition wall.

### DESCRIPTION

### Technical Field

The present invention relates to a light-transmitting device module used in a photoelectric sensor.

### Background Art

A light transmitting device comprising a light source and an optical fiber, and configured to incident light radiating from the light source into the interior of the optical fiber, and a sensor comprising this kind of light transmitting device is known.

In a case of light emitted from the light source at a wide angle of about 120 degrees, only a portion of the emitted light from the light source is incident on the inside of the optical fiber, leading to reduced coupling efficiency. Therefore, various techniques have been proposed to increase the coupling efficiency.

In the following prior art 1, a reflector is provided between the light-emitting surface of the light-emitting element and the incident cross-section of the optical fiber, and a reflective space having a parabolic cross-section is formed inside the reflector. With the reflector provided, light emitted at a wide-angle from the light source is reflected from the parabolic-shaped reflection surface formed inside the reflector and enters the optical fiber through the mating cross-section of the optical fiber. As a result, the amount of light incident from the light source to the coupling end of the optical fiber is increased, and the coupling efficiency of the light is improved.

In the absence of the reflector, the light coupling efficiency was very low, about 13%, because the inner part of the light radiated from the light source escapes to the outside without entering the optical fiber, but with the inclusion of the reflector, the light coupling efficiency has been significantly increased.

However, in the past, a light receiving element for observation (a monitoring Photo-Diode chip) to observe whether the intensity of light radiated from the light source is maintained at an appropriate level is not provided separately, or even if the light receiving element for observation is provided inside the photoelectric sensor, it is arranged in a location where is separated from the light source as shown in Prior Art 2 below, which has the disadvantage of being inefficient.

To improve these disadvantages, a method is proposed in which the light transmitting element corresponding to the light source and the light receiving element for observation are installed inside a single frame.

When a light emitting element and a light receiving element for observation are arranged inside a single frame, a problem may arise that real-time observation of the light intensity of the light emitting element, which is the original purpose of the observation receiving element, is not possible when the light emitted through the optical fiber is irradiated onto a reflector and then reintroduced into the light emitting element because the intensity of the reflected light is too large.

For example, if the light emitted through the fiber is irradiated to a highly reflective object, some of the light may be incident on the light receiving element for observation. In this case, the output of the light emitting element for observation increases, causing a misjudge that the output of the light-transmitting element has increased, and as a result, the output of the light-transmitting element is lowered, which may cause a malfunction of the photoelectric sensor.
Prior art 1: Korean Patent KR10-1190334 (Oct. 5, 2012)
Prior art 2: Japanese Patent publication JPH06-342938 (Dec. 13, 1994)

### DISCLOSURE

### Technical Problem

The present invention is proposed to address the above-mentioned problems.

Specifically, it is an object of the invention to provide a light transmitting device module in which, in a structure in which a light transmitting element and a light receiving element for observation are arranged within a single frame, the amount of light reflected from a highly reflective body and retrograded inside an optical fiber to reach the light receiving element for observation can be appropriately adjusted.

### Technical Solution

A light transmitting device module according to an embodiment of the present invention to achieve the above objectives comprises: a metal frame; a light-transmitting device chip mounted on an upper surface of the metal frame; a light-receiving device chip mounted on the metal frame to monitor an intensity of light emitted by the light-transmitting device chip, and located at a point spaced apart from the light-transmitting device chip; a housing coupled to the upper surface of the metal frame, spatially partitioning the light-transmitting device chip and the light-receiving device chip; and a reflector disposed on an upper surface of the housing, wherein the housing includes: a first opening opened to receive the light-transmitting device chip; a second opening opened to receive the light-receiving device chip; and a partitioning wall partitioning the first opening and the second opening, and wherein a light passage groove is formed in the partitioning wall.

The light passage groove steps down a predetermined depth from an upper surface of the partitioning wall.

A length of the light passage groove is at least half of a length of the first opening.

A length of the second opening is formed to be longer than a length of the first opening.

A depth of the light passage groove is at least half of a height of the partitioning wall.

A reflector mounting groove is formed in the housing, and the reflector mounting groove steps down a predetermined depth from the upper surface of the housing.

The first opening and the second opening are openings passing through a bottom of the reflector mounting groove to a lower surface of the housing.

The reflector comprises: a body portion; and a mounting portion extending from a lower surface of the body portion and received in the reflector mounting groove.

The body portion has a window groove formed therein, and the window groove steps down from an upper surface of the body portion to a predetermined size and depth.

The light-transmitting device module further comprises a window mounted in the window groove.

The light guide hole extends from a bottom of the window groove and is formed through a bottom of the mounting portion, and a longitudinal section of the light guide hole forms a parabolic curve of which a width increases towards the top.

### Advantageous Effects

A light-transmitting device module according to an embodiment of the present invention having the above configuration has the following effects.

First, by enabling the light-transmitting device chip and the light-receiving device chip for observation to be disposed inside a single housing, the space utilization in the sensor is improved and errors caused by assembly errors are minimized compared to a structure in which the light-transmitting device chip and the light-receiving device chip for observation are disposed separately in the sensor.

Second, by forming a partition between the light-transmitting device chip and the light-receiving device chip for observation, and forming a light-passage groove in the partition that allows an appropriate amount of light to reach the light-receiving device chip for observation, the intensity of light incident from the light-transmitting device chip to the light-receiving device chip for observation is appropriately adjusted.

Third, by minimizing the influence of highly reflective objects, the possibility of misjudging the light intensity of the light-transmitting device chip is reduced, and as a result, the possibility of malfunction of the photoelectric sensor can be minimized.

### DESCRIPTION OF DRAWINGS

FIG. 1 is an exterior perspective view of a light-transmitting device module according to an embodiment of the present invention.

FIG. 2 is an exploded perspective view of the above light-transmitting device module.

FIG. 3 is a perspective view of a reflector comprising a light-transmitting device module according to an embodiment of the present invention.

FIG. 4 is a longitudinal sectional view of a reflector being cut along 4-4 of FIG. 3.

FIG. 5 is a perspective view of a light-transmitting device module showing a housing coupled to an upper surface of a metal frame on which a light-transmitting device chip and a light-receiving device chip are mounted.

FIG. 6 is a longitudinal sectional view of a light-transmitting device module according to an embodiment of the present invention in which an incision is made along 6-6 of FIG. 1.

### MODE FOR INVENTION

Hereinafter, a light-transmitting device module according to an embodiment of the present invention will be described in detail with reference to the following drawings.

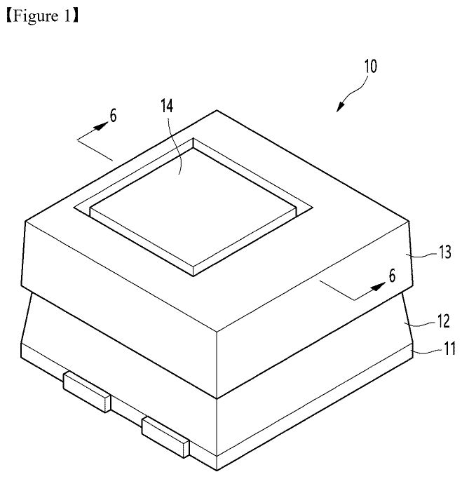

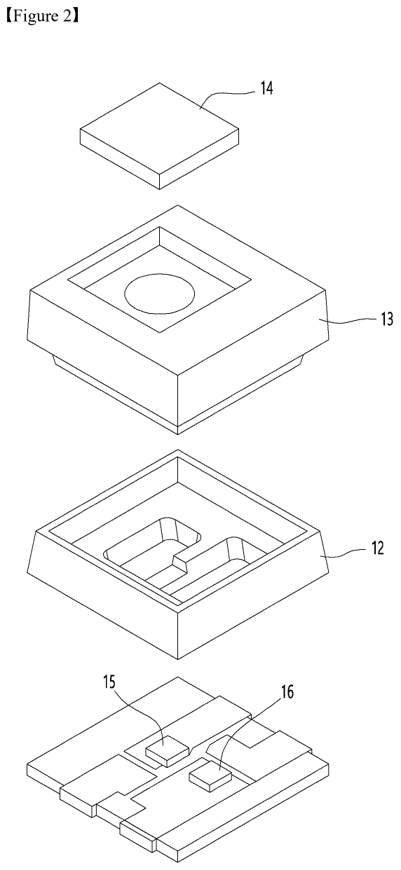

FIG. 1 is an exterior perspective view of a light-transmitting device module according to an embodiment of the present invention, and FIG. 2 is a disassembled perspective view of the light-transmitting device module.

Referring to FIGS. 1 and 2, a light-transmitting device module 10 according to an embodiment of the present invention comprises a metal frame 11, a light-transmitting device chip (light emitting device chip) 15 mounted on the metal frame 11, and a monitoring Photo-Diode chip 16 (hereinafter referred to as a light-receiving device chip), a housing 12 placed on an upper surface of the metal frame 11, a reflector 13 placed on an upper surface of the housing 12, and a window 14 placed on an upper surface of the reflector 13.

More specifically, the metal frame 11 is defined as a metal substrate on which a semiconductor chip is mounted. The light-transmitting device chip 15 and the light-receiving device chip 16 are mounted on the upper surface of the metal frame 11, but are spaced apart from each other at predetermined intervals in the horizontal direction. Depending on the design conditions, the horizontal line passing through the center of the light-transmitting device chip 15 and the horizontal line passing through the center of the light-receiving device chip 16 may form the same line, or may form parallel lines spaced at predetermined interval. The position of the light-receiving device chip 16 can be adjusted to adjust the amount of light incident on the light-receiving device chip 16.

The housing 12 separates the receiving space of the light-transmitting device chip 15 and the light-receiving device chip 16, and limits the amount of light transmitted to the light-receiving device chip 16.

The reflector 13 is provided to increase the coupling efficiency of the optical fiber with the light-transmitting device chip 15. Here, the coupling efficiency may be explained to mean the ratio of light emitted from the light-transmitting device chip 15 and incident into the optical fiber connected to the reflector 13. In other words, a high coupling efficiency may be understood to mean that the amount of light emitted from the light-transmitting device chip 15 and incident into the optical fiber is greater than the amount of light escaping outside the optical fiber, and the opposite is true for a low coupling efficiency.

The reflector 13 may be made of a metallic material with a gold-plated surface.

The window 14 covers an opening formed on the upper surface of the reflector 13 to block dust or foreign matter from entering the inside of the light-transmitting device module 10, thereby protecting the light-transmitting device chip 15 and light-receiving device chip 16. One end of the optical fiber, i.e., the light-introducing end, is secured to the window 14, so that light emitted from the light-transmitting device chip 15 passes through the window 14.

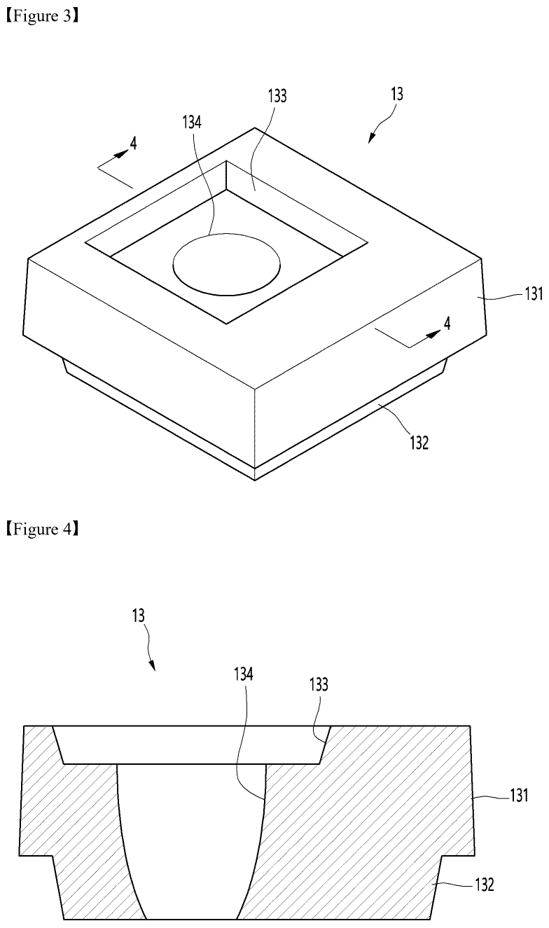

FIG. 3 is a perspective view of a reflector comprising a light-transmitting device module according to an embodiment of the present invention, and FIG. 4 is a longitudinal sectional view of the reflector being incised along 4-4 of FIG. 3.

Referring to FIGS. 3 and 4, a reflector 13 constituting a light-transmitting device module 10 according to an embodiment of the present invention includes a body portion 131 and a mounting portion 132 extending downwardly from a low surface of the body portion 131.

The body portion 131 and the mounting portion 132 may be molded as a single unit, for example by injection molding.

The body portion 131 has a window groove 133 and a light guide hole 134 formed therein. The window groove 133 and the light guide hole 134 are located right above the light-transmitting device chip 15. Thus, the window groove 133 and the light guide hole 134 are formed at a position biased from a center towards one edge of the reflector 13.

In detail, the window groove 133 is formed with steps at a predetermined depth from the upper surface of the body portion 131. The window recess 133 may be in the shape of a circle or a polygon including a square. Then, the window 14 is mounted on the window groove 133.

The light guide hole 134 extends from the bottom of the window groove 133 and penetrates the bottom of the mounting portion 132. Further, the longitudinal section of the light guide hole 134 may form a truncated parabola, which may form an upwardly expanding parabola.

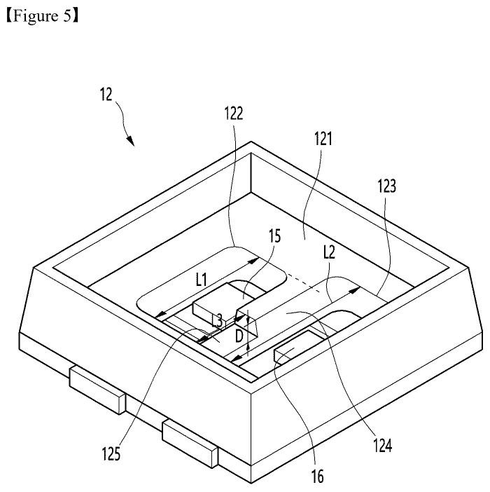

FIG. 5 is a perspective view of a light-transmitting device module showing a light-transmitting device chip and a light-receiving device chip mounted on an upper surface of a metal frame with a housing.

Referring to FIG. 5, a housing 12 comprising a light-transmitting device module 10 according to an embodiment of the present invention is formed with a reflector mounting groove 121, a first opening 122 (light transmitting part), a second opening 123 (light receiving part), a partitioning wall 124, and a light passage groove 125.

In detail, the reflector mounting groove 121 is a groove in which the mounting portion 132 of the reflector 13 is received, and is formed at a predetermined depth stepwise from the upper surface of the housing 12. The reflector mounting groove 121 is stepped in a shape corresponding to the shape of the mounting portion 132, and may be sloped on the sides to decrease in cross-sectional area towards the bottom as shown, but is not necessarily limited thereto.

The depth of the reflector receiving groove 121 is formed to be equal to or less than the length of the mounting portion 132, so that the mounting portion 132 is not spaced from the bottom of the reflector receiving groove 121 due to molding tolerances. If, with the reflector 13 coupled to the housing 12, the bottom of the mounting portion 132 is spaced apart from the reflector mounting groove 121, the light coupling efficiency will be reduced, so it is preferable that the length of the mounting portion 132 is designed to be greater than the depth of the reflector mounting groove 121.

The first opening 122 is an opening in which the light-transmitting device chip 15 is received, and the second opening 123 is an opening in which the light-receiving device chip 16 is received. The partitioning wall 124 is a wall partitioning the first opening 122 and the second opening 123, and adjusts the amount of light that is emitted from the light-transmitting device chip 15 and incident on the light-receiving device chip 16.

The length L1 of the first opening 122 may be designed to be different from the length L2 of the second opening 123, for example, the length L2 of the second opening 123 may be designed to be longer than the length L1 of the first opening 122. By designing the length L2 of the second opening 123 to be longer than the length L1 of the first opening 122, the degree of freedom for the installation position of the light receiving element is increased.

The light passage groove 125 is formed to allow light from the first opening 122 to pass through the second opening 123. The depth D of the light passage groove 125 may be appropriately designed to suit the required amount of light incident on the light-receiving device chip 16. For example, the depth D of the light passage groove 125 may be designed to be greater than half of the height H1 of the partitioning wall 124, but is not necessarily limited thereto.

Further, the length L3 of the light passage groove 125 may be designed according to the required amount of light incident on the light-receiving device chip 16. For example, the length L3 of the light passage groove 125 may be set to more than half of the length L1 of the light transmitting member, but is not necessarily limited thereto.

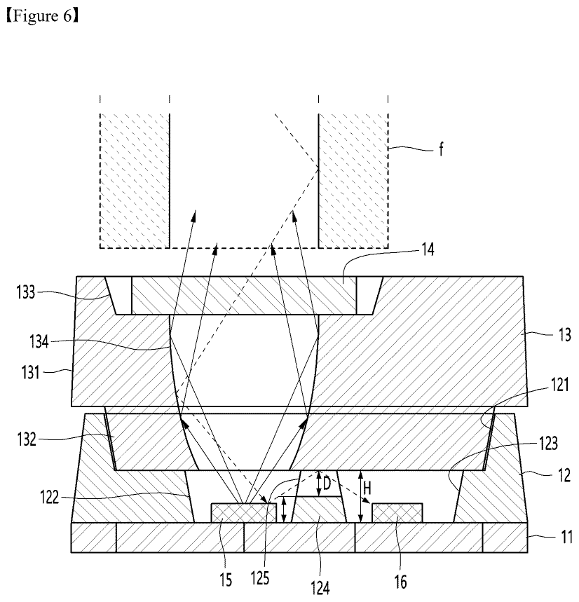

FIG. 6 is a longitudinal sectional view of a light-transmitting device module according to an embodiment of the present invention, which is incised along the lines 6-6 of FIG. 1.

Referring to FIG. 6, light irradiated by the light-transmitting device chip 15 is reflected after striking the surface of the optical guide hole 134 formed in the reflector 13, and a portion of the reflected light is incident into the optical fiber f, while the remaining portion escapes out of the optical fiber f and is dissipated.

In detail, by disposing the reflector 13 in which a parabolic-shaped light guide hole 134 is formed between the optical fiber f and the light-transmitting device chip 15, the amount of light incident from the light-transmitting device chip 15 onto the optical fiber f is increased, i.e., the light coupling efficiency is improved.

Furthermore, as the gap between the lowermost end of the light guide hole 134 and the light-transmitting device chip 15 increases, the light coupling efficiency decreases, so the gap is preferably kept at least 0.26 mm or less. As described above, by designing the length of the mounting portion 132 of the reflector 13 to be larger than the depth of the reflector mounting groove 121 of the housing 12, an increase in the gap between the bottom end of the light guide hole 134 and the light-transmitting device chip 15 does not occur even if assembly tolerances occur.

Further, by appropriately designing the depth D of the light passage groove 125, the intensity of light incident on the light-receiving device chip 16 can be appropriately maintained.

1. A light-transmitting device module, comprising:
a metal frame;
a light-transmitting device chip mounted on an upper surface of the metal frame;
a light-receiving device chip mounted on the metal frame to monitor an intensity of light emitted by the light-transmitting device chip, and located at a point spaced apart from the light-transmitting device chip;
a housing coupled to the upper surface of the metal frame, spatially partitioning the light-transmitting device chip and the light-receiving device chip; and
a reflector disposed on an upper surface of the housing,
wherein the housing includes:
a first opening opened to receive the light-transmitting device chip;
a second opening opened to receive the light-receiving device chip; and
a partitioning wall partitioning the first opening and the second opening,
and wherein a light passage groove is formed in the partitioning wall.

2. The light-transmitting device module according to claim 1, wherein the light passage groove steps down a predetermined depth from an upper surface of the partitioning wall.

3. The light-transmitting device module according to claim 2, wherein a length of the light passage groove is at least half of a length of the first opening.

4. The light-transmitting device module according to claim 2, wherein a length of the second opening is formed to be longer than a length of the first opening.

5. The light-transmitting device module according to claim 2, wherein a depth of the light passage groove is at least half of a height of the partitioning wall.

6. The light-transmitting device module according to claim 1, wherein a reflector mounting groove is formed in the housing,
and wherein the reflector mounting groove steps down a predetermined depth from the upper surface of the housing,

7. The light-transmitting device module according to claim 6, wherein the first opening and the second opening are openings passing through a bottom of the reflector mounting groove to a lower surface of the housing.

8. The light-transmitting device module according to claim 6, wherein the reflector comprises:
a body portion; and
a mounting portion extending from a lower surface of the body portion and received in the reflector mounting groove.

9. The light-transmitting device module according to claim 8, wherein the body portion has a window groove formed therein.
and wherein the window groove steps down from an upper surface of the body portion to a predetermined size and depth.

10. The light-transmitting device module according to claim 9, further comprising a window mounted in the window groove.

11. The light-transmitting device module according to claim 9, wherein the light guide hole extends from a bottom of the window groove and is formed through a bottom of the mounting portion,
and wherein a longitudinal section of the light guide hole forms a parabolic curve of which a width increases towards the top.
